(19) United States
(12) Patent Application Publication
(10) Pub. No.: US 2023/0016598 A1
(43) Pub. Date: Jan. 19, 2023

(54) TREATMENT APPARATUS FOR TREATING WORKPIECE

(71) Applicant: DISCO CORPORATION, Tokyo (JP)

(72) Inventor: Satoshi HANAJIMA, Tokyo (JP)

(21) Appl. No.: 17/936,819

(22) Filed: Sep. 29, 2022

Related U.S. Application Data
(63) Continuation-in-part of application No. 16/430,709, filed on Jun. 4, 2019.

(30) Foreign Application Priority Data
Jun. 12, 2018 (JP) 2018-111817
Jun. 12, 2018 (JP) 2018111817

(51) Int. Cl. B08B 13/00; B08B 3/02

(52) U.S. Cl. CPC B08B 13/00; B08B 3/022

(57) ABSTRACT

A treatment apparatus including a chuck table, a table base, a servo motor that rotates the table base, and a determination unit that determines the kind of the chuck table mounted to the table base is provided. The determination unit includes a torque recording section in which a torque outputted by the servo motor when rotating the table base is recorded on the basis of the kind of the chuck table, and a determination section that collates the torque outputted by the servo motor with the torque recording section, to thereby determine the kind of the chuck table.

### CROSS-REFERENCE TO RELATED APPLICATION

This application is a continuation-in-part of prior U.S. application Ser. No. 16/430,709, filed Jun. 4, 2019.

### BACKGROUND OF THE INVENTION

### Field of the Invention

The present invention relates to a treatment apparatus capable of performing a treatment such as processing or cleaning of a workpiece.

### Description of the Related Art

In steps for forming device chips including semiconductor devices or optical devices from a workpiece such as a silicon substrate and a sapphire substrate, various treatment apparatuses are used. For instance, such treatment apparatuses as a cutting apparatus for cutting a workpiece formed with a plurality of devices on a device basis, a laser treatment apparatus for performing laser processing of the workpiece, a grinding apparatus for grinding the workpiece to thin the workpiece to a predetermined thickness, and a cleaning apparatus for cleaning the processed workpiece are used. Thus, in the treatment apparatus, a treatment such as processing or cleaning of the workpiece is conducted. These treatment apparatuses include a chuck table for holding the workpiece, and a treatment unit for performing a predetermined treatment of the workpiece. The chuck table includes a porous member at an upper surface thereof, and is provided therein with a suction source connected to the porous member. When a workpiece is mounted on the chuck table and the suction source is operated, a negative pressure acts on the workpiece, whereby the workpiece is suction held onto the chuck table. The treatment apparatus treat the workpiece held by the chuck table, by the treatment unit.

In these treatment apparatuses, the chuck table is exchangeable, and, for suction holding the workpiece of various sizes by the chuck table, a chuck table provided with a holding surface corresponding to the size, shape and the like of the workpiece is mounted. If a chuck table corresponding to the workpiece is not mounted on the treatment apparatus, not only the workpiece is not correctly held and a suitable treatment is not performed, but also an unexpected shock or the like may be exerted on the workpiece by the treatment, resulting in breakage of the workpiece. In addition, a chuck table capable of holding workpieces of a plurality of sizes without exchanging the chuck table has been known (see, for example, Japanese Patent Laid-Open No. Hei 7-153721). When this chuck table is used, an operation of exchanging the chuck table can be omitted. In the case of using this chuck table, however, treatment cost of the workpiece would be raised, since the chuck table itself and a suction mechanism connected to the chuck table is complicated in configuration.

### SUMMARY OF THE INVENTION

In general, a suitable one of chuck tables is selected according to the kind, size and the like of the workpiece by the operator of the treatment apparatus or the like. However, there may be cases where the operator of the treatment apparatus or the like makes a mistake in selecting the chuck table, and an unsuitable chuck table is mounted to the treatment apparatus. In order to prevent a mistake from occurring in mounting the chuck table, staff in charge of confirmation may be added, or the treatment apparatus may be equipped with a large scale confirmation mechanism, but such an approach leads to an increase in the treatment cost of the workpiece.

Accordingly, it is an object of the present invention to provide a treatment apparatus capable of determining the kind of a chuck table mounted thereto.

In accordance with an aspect of the present invention, there is provided a treatment apparatus including a chuck table that has a holding surface mounting a workpiece thereon and holds the workpiece, a table base to which the chuck table is detachably fixed, a servo motor that rotates the table base around a rotational axis along a direction perpendicular to the holding surface of the chuck table mounted to the table base, a treatment unit that treats the workpiece held by the chuck table, and a determination unit that determines the kind of the chuck table mounted to the table base. The determination unit includes: a torque recording section in which a torque outputted by the servo motor when rotating the table base is recorded on the basis of the kind of the chuck table mounted to the table base; a determination section that measures a torque outputted by the servo motor when rotating the table base with the chuck table mounted thereto, and collates the measured torque with each of the torques recorded in the torque recording section, to thereby determine the kind of the chuck table; and a reporting section that reports a result of determination carried out by the determination section.

Preferably, the torque measured by the determination section is one of or both a torque during acceleration until the table base reaches a predetermined rotational speed and a torque during deceleration until the table base is stopped from the predetermined rotational speed.

In addition, preferably, the treatment unit is a cleaning unit cleaning the workpiece.

The treatment apparatus according to an aspect of the present invention includes the table base to which the chuck table is detachably fixed, and the servo motor that rotates the table base. The chuck table is detachably fixed onto the table base. When rotating the chuck table mounted to the table base, the table base is rotated by the servo motor.

The treatment apparatus includes the determination unit that determines the kind of the chuck table mounted to the table base. The determination unit includes the torque recording section in which the torque outputted by the servo motor is recorded on the basis of the kind of the chuck table mounted to the table base. In addition, the determination unit further includes the determination section that measures the torque outputted by the servo motor when rotating the table base with the chuck table mounted thereto and collates the measured torque with each of the torques recorded in the torque recording section. The determination section determines the kind of the chuck table related to that torque of the torques recorded in the torque recording section which coincides with the measured torque, as the kind of the chuck table mounted to the table base. Since the treatment apparatus can determine the kind of the chuck table mounted, it can also issue an alarm or the like in the case where the kind of the chuck table determined is unsuited to the workpiece to be treated.

Therefore, according to an aspect of the present invention, a treatment apparatus is provided which can determine the kind of a chuck table mounted thereto.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically depicting an example of a treatment apparatus;

FIG. 2 is a perspective view schematically depicting a cleaning unit as an example of a treatment unit;

FIG. 3A is a sectional view schematically depicting a chuck table;

FIG. 3B is a sectional view schematically depicting another chuck table; and

FIG. 4 depicts a graph schematically depicting the relation between rotational speed of a servo motor and time and a graph schematically depicting the relation between torque of the servo motor and time.

### DETAILED DESCRIPTION OF THE PREFERRED EMBODIMENT

An embodiment of a treatment apparatus according to an aspect of the present invention will be described referring to the attached drawings. The treatment apparatus according to the present embodiment is a treatment apparatus to be used in steps of forming device chips each including a semiconductor device such as an integrated circuit (IC) or an optical device such as a light emitting diode (LED), from a workpiece, such as a silicon substrate or a sapphire substrate. The treatment apparatus is, for example, a cutting apparatus for cutting the workpiece on the basis of each device, a laser treatment apparatus for laser processing, a grinding apparatus for grinding the workpiece to thin workpiece to a predetermined thickness, or the like. A further example of the treatment apparatus is a cleaning apparatus for cleaning the processed workpiece. In other words, in the treatment apparatus, a treatment such as processing or cleaning is applied to the workpiece.

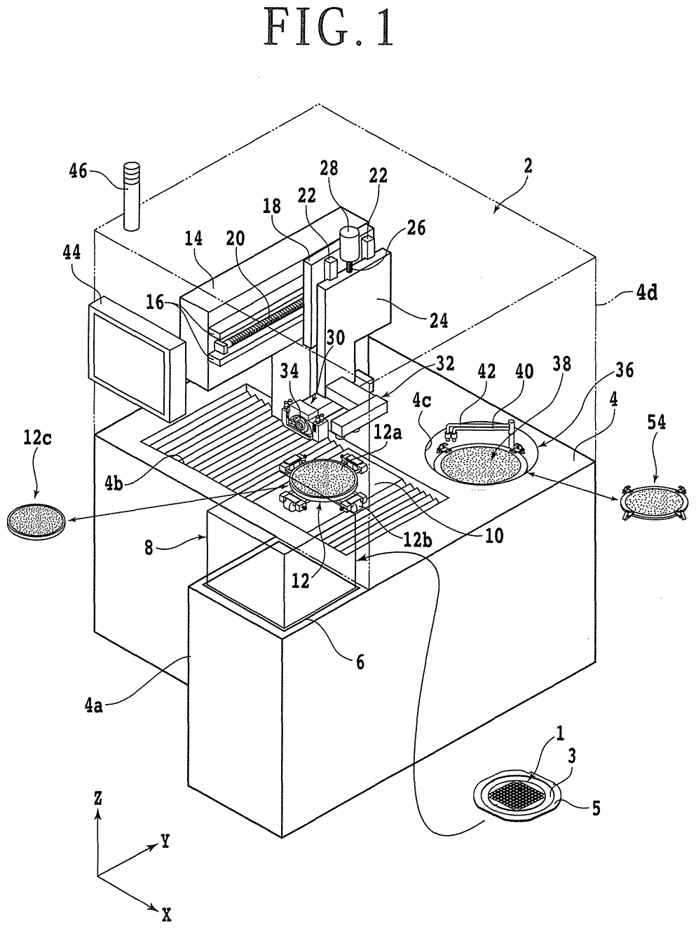

FIG. 1 is a perspective view schematically depicting a treatment apparatus according to the present embodiment. A treatment apparatus 2 illustrated in FIG. 1 is a cutting apparatus for cutting a workpiece. In the treatment apparatus 2 cleaning of the workpiece which has been cut is also performed. The present embodiment will be described below taking as an example a case where the treatment apparatus 2 is a cutting apparatus. The treatment apparatus 2 includes a base 4 for supporting each of components of the apparatus. A cassette support base 6 that is moved up and down is provided on an upper surface of a projected portion 4a on a front side of the base 4. A cassette 8 for accommodating a plurality of workpieces 1, is mounted on an upper surface of the cassette support base 6. Note that in FIG. 1, only the outline of the cassette 8 is depicted, for convenience of explanation.

The workpiece 1 is a disk-shaped wafer, for example. Division lines (streets) arranged in a grid pattern are set on the side of a front surface of the wafer, and the front surface is partitioned into a plurality of regions. A device such as an IC and an LED is formed in each of the partitioned regions, and, when the workpiece 1 is divided along the division lines, individual device chips are formed. Note that the workpiece 1 may not be a disk-shaped wafer formed of a semiconductor material such as silicon, and the material, shape, structure and the like of the workpiece 1 are not limited. For example, a rectangular substrate formed of such a material as ceramic, resin, and metal may also be used as the workpiece 1. The kind, number, layout and the like of the devices are also not limited. A tape 3 having a diameter larger than the diameter of the workpiece 1 is adhered to the back surface side of the workpiece 1, and an annular frame 5 formed from a metal or the like is adhered to an outer peripheral portion of the tape 3. The workpiece 1 is accommodated in the cassette 8 in the state of being united with the tape 3 and the annular frame 5, and is carried into and processed by the treatment apparatus 2.

The treatment apparatus 2 includes a box-type housing 4d on the base 4, and the main components are accommodated in the inside of the housing 4d. In FIG. 1, only the outline of the housing 4d is depicted in alternate long and two short dashes line, for convenience of explanation. The housing 4d is provided in the vicinity of the cassette support base 6 with a carrying-in/out port (not illustrated), and a frame unit possessing the workpiece 1 is carried into and out of the inside of the housing 4d through the carrying-in/out port. The treatment apparatus 2 includes a carrying mechanism (not illustrated) that takes out the frame unit accommodated in the cassette 8 mounted on the cassette support base 6, and places the frame unit on a chuck table 12 to be described later.

The upper surface of the base 4 is formed, in the vicinity of the cassette support base 6, with a rectangular opening 4b which is long in an X-axis direction (front-rear direction, processing feeding direction). An X-axis movable table 10 is provided in the opening 4b. The chuck table 12 that holds the workpiece 1 is provided on the upper side of the X-axis movable table 10. A porous member is disposed at an upper surface of the chuck table 12, and an upper surface of the porous member constitutes a holding surface for holding the workpiece 1. The chuck table 12 is provided at an outer peripheral portion thereof with clamps 12b for clamping the annular frame 5 included in the frame unit mounted on the holding surface 12a. The porous member is connected to a suction source (not illustrated) through a suction passage (not illustrated) formed inside the chuck table 12 and a table base (not illustrated). When the workpiece 1 is mounted on the holding surface 12a through the tape 3 and the suction source is operated to cause a negative pressure to act on the workpiece 1 through the suction passage and the porous member, the workpiece 1 is suction held on the chuck table 12. The chuck table 12 is fixed onto the table base, and the table base is connected to a servo motor (not illustrated). When the servo motor is operated, the table base is rotated, and the chuck table 12 fixed onto the table base is rotated around an axis perpendicular to the holding surface 12a.

On a lateral side of the opening 4b in the upper surface of the base 4, there is provided a support section 14 provided with an arm portion projecting to the upper side of the opening 4b along a Y-axis direction perpendicular to the X-axis direction. A pair of Y-axis guide rails 16 parallel to the Y-axis direction are disposed on a front side of the arm portion of the support section 14. A Y-axis moving plate 18 is slidably mounted to the Y-axis guide rails 16. The Y-axis moving plate 18 is provided on the back surface side (rear surface side) thereof with a nut section (not illustrated), and a Y-axis ball screw 20 parallel to the Y-axis guide rails 16 is in screw engagement with the nut section. A Y-axis pulse motor (not illustrated) is connected to one end portion of the Y-axis ball screw 20. When the Y-axis ball screw 20 is rotated by the Y-axis pulse motor, the Y-axis moving plate 18 is moved in the Y-axis direction along the Y-axis guide rails 16.

A pair of Z-axis guide rails 22 parallel to a Z-axis direction, which is perpendicular to the X-axis direction and the Y-axis direction, are provided on a front surface of the Y-axis moving plate 18. A Z-axis moving plate 24 is slidably mounted to the Z-axis guide rails 22. The Z-axis moving plate 24 is provided on the back surface side (rear surface side) thereof with a nut section (not illustrated), and a Z-axis ball screw 26 parallel to the Z-axis guide rails 22 is in screw engagement with the nut section. A Z-axis pulse motor 28 is connected to one end portion of the Z-axis ball screw 26. When the Z-axis ball screw 26 is rotated by the Z-axis pulse motor 28, the Z-axis moving plate 24 is moved in the Z-axis direction along the Z-axis guide rails 22.

A treatment unit is provided at a lower portion of the Z-axis moving plate 24. The treatment unit possessed by the treatment apparatus 2 which is a cutting apparatus is, for example, a cutting unit 30 for cutting the workpiece 1. The cutting unit 30 includes a circular annular cutting blade 34 mounted to one end side of a spindle serving as a rotary shaft. In addition, a camera unit (imaging unit) 32 for imaging the workpiece 1 and the like is provided at a position adjacent to the cutting unit 30. When the workpiece 1 held by the chuck table 12 is imaged by the camera unit 32, the division lines (streets) set on the front surface of the workpiece 1 can be detected.

When the Y-axis moving plate 18 is moved in the Y-axis direction, the cutting unit 30 and the camera unit 32 are put into indexing feeding in the Y-axis direction. In addition, when the Z-axis moving plate 24 is moved in the Z-axis direction, the cutting unit 30 and the camera unit 32 are moved upward or downward. At the time of cutting the workpiece 1, the treatment apparatus 2 detects the position of the division line set on the front surface of the workpiece 1 by use of the camera unit 32, and rotates the chuck table 12 to align the extending direction of the division line with a processing feeding direction (X-axis direction). Then, the annular cutting blade 34 mounted to the cutting unit 30 is rotated, the cutting unit 30 is lowered to a predetermined height, the chuck table 12 is put to processing feeding, and the cutting blade 34 is thereby caused to cut into the workpiece 1.

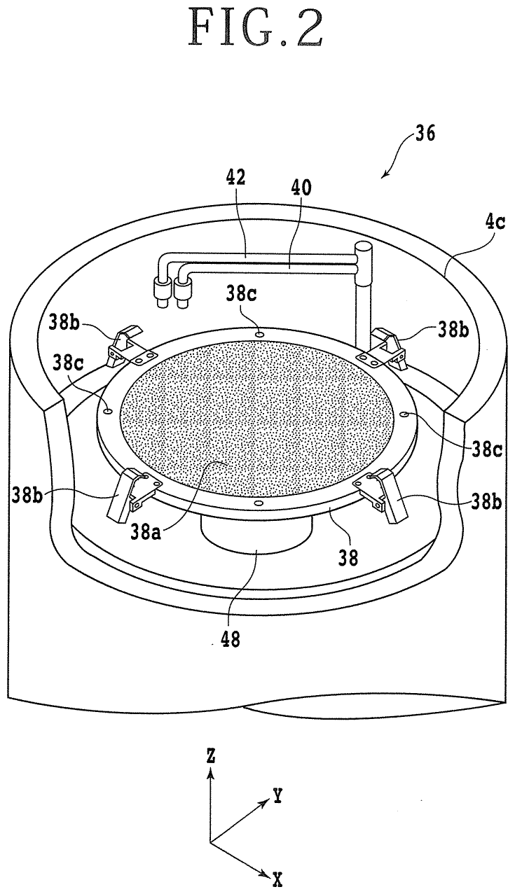

At a position on the opposite side of the opening 4b from the cassette support base 6, a circular opening 4c is formed. In the opening 4c is provided a cleaning unit 36 for treatment such as cleaning of the workpiece 1 which has been cut. Thus, the treatment apparatus 2 includes the cleaning unit 36 in addition to the cutting unit 30, as a treatment unit. The cleaning unit 36 provided in the opening 4c will be described in detail referring to FIG. 2. FIG. 2 is a perspective view schematically depicting the cleaning unit 36 as a treatment unit.

A chuck table 38 for holding the workpiece 1 is provided inside the opening 4c. A porous member is disposed at an upper surface of the chuck table 38, and an upper surface of the porous member constitutes a holding surface 38a for holding the workpiece 1 thereon. The porous member is connected to a suction source (not illustrated) through a suction passage (not illustrated) formed inside the chuck table 38. When the frame unit including the workpiece 1 is mounted on the holding surface 38a and the suction source is operated to cause a negative pressure to act on the workpiece 1, the workpiece 1 is suction held onto the chuck table 38. The chuck table 38 is provided at an outer peripheral portion thereof with clamps 38b for clamping the annular frame 5 included in the frame unit mounted on the holding surface 38a. The clamp 38b is provided with a weight at a lower end portion thereof, and is provided at an upper end portion thereof with a grasping section that makes contact with the annular frame 5. When the chuck table 38 is rotated at a high speed around an axis perpendicular to the holding surface 38a, the weights are moved toward the outer periphery side by centrifugal forces, and the grasping sections are tilted down toward the inner circumference side, to grasp the annular frame 5.

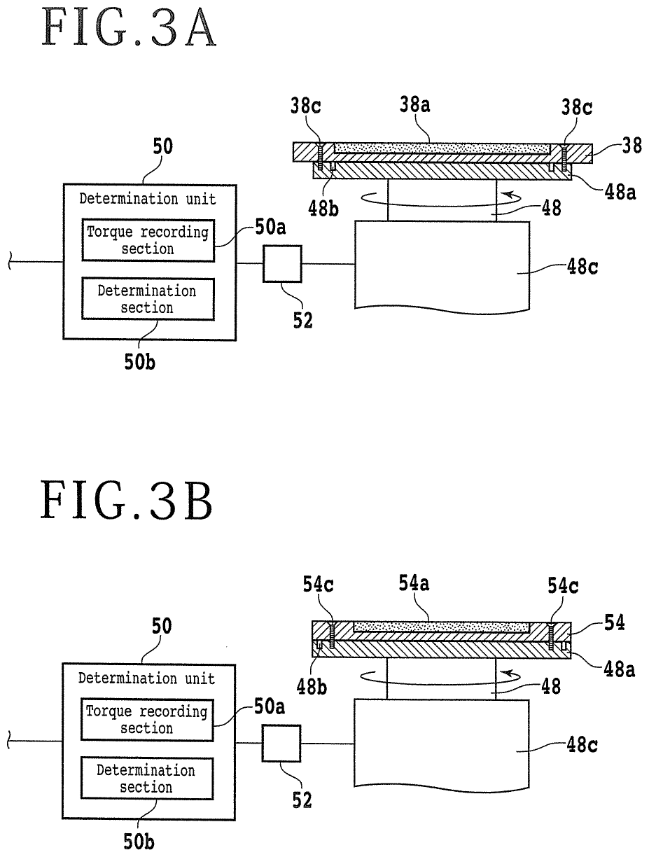

FIG. 3A is a sectional view schematically depicting the chuck table 38. As illustrated in FIG. 3A, the chuck table 38 is mounted onto the table base 48a. The table base 48a is rotatably supported at an upper end of a rotary shaft 48 of the servo motor 48c. The chuck table 38 is provided in its outer peripheral portion with insertion holes for fixing screws 38c fastened into tapped holes 48b provided in an upper surface of the table base 48a when the chuck table 38 is mounted to the table base 48a. In addition, the upper surface of the table base 48a is provided with tapped holes 48b at positions corresponding to the insertion holes in a chuck table 54 (see FIG. 3B) of other size. Into the tapped holes 48b are fastened fixing screws 54c when the chuck table 54 is mounted to the table base 48a. When the servo motor 48c is operated to rotate the rotary shaft 48, the chuck table 38 can be rotated around an axis along a direction perpendicular to the holding surface 38a. A motor driver 52 for controlling the rotation of the servo motor 48c is connected to the servo motor 48c. The motor driver 52 can control the servo motor 48c in such a manner that the servo motor 48c is rotated at a predetermined speed, and it can detect a torque from, for example, electric power consumed by the servo motor 48c in this instance.

As depicted in FIG. 2, the cleaning unit 36 includes a cleaning nozzle 40 for jetting a cleaning liquid from above to the workpiece 1 held by the chuck table 38. Further, the cleaning unit 36 includes a drying nozzle 42 for removing the cleaning liquid adhered to the workpiece 1 and drying the workpiece 1, after the cleaning of the workpiece 1. The cleaning nozzle 40 and the drying nozzle 42 are connected to an upper end of a shaft portion extending along the Z-axis direction on the outer periphery side of the chuck table 38, and, by rotating the shaft portion, they can be moved over the chuck table 38.

At the time of a cleaning treatment of the cut workpiece 1 by the cleaning unit 36, first, the frame unit is mounted on the chuck table 38, and the frame unit is suction held by the chuck table 38. Next, the servo motor 48c is operated to rotate the chuck table 38. Then, while jetting a cleaning liquid such as pure water downward from the cleaning nozzle 40, a jet port of the cleaning nozzle 40 is reciprocated over the workpiece 1, to clean the surface of the workpiece 1 by the cleaning liquid. Thereafter, while jetting a gas such as dry air downward from the drying nozzle 42, a jet port of the drying nozzle 42 is reciprocated over the workpiece 1, to blow off the cleaning liquid adhered to the frame unit including the workpiece 1. The frame unit including the workpiece 1 thus cleaned is carried from the chuck table 38 into the cassette 8 by the aforementioned carrying unit.

As depicted in FIG. 1, a touch panel type display monitor 44 is provided at one side surface of the housing 4d of the treatment apparatus 2. The contents of the treatment performed by the treatment apparatus 2, the state of progress of the treatment and the like are displayed on the display monitor 44. In addition, when an abnormal situation is generated in the treatment apparatus 2, an alarm is displayed on the display monitor 44. Further, the operator of the treatment apparatus 2 or other person can input various instructions to the treatment apparatus 2 by use of the display monitor 44. An alarm lamp 46 is provided at an upper surface of the housing 4d of the treatment apparatus 2. The alarm lamp 46 includes, for example, a green lamp and a red lamp. In the case where the treatment apparatus 2 is free from abnormality and is operating suitably, the alarm lamp 46 turns on the green lamp. When some abnormal situation is generated in the treatment apparatus 2, the red lamp is turned on to warn the operator of the treatment apparatus 2 or other person. Note that the display monitor 44 and the alarm lamp 46 function also as a reporting section possessed by a determination unit 50 which will be described later.

The chuck tables 12 and 38 to be mounted to the treatment apparatus 2 are exchangeable, and a suitable one is selected by the operator, supervisor or the like of the treatment apparatus 2 according to the size, shape and the like of the workpiece 1, and is mounted to the treatment apparatus 2. In FIG. 1 is depicted a chuck table 12c which is exchangeable with the chuck table 12 and is different from the chuck table 12 in the size of the holding surface 12a. In addition, in FIG. 1 is depicted the chuck table 54 which is exchangeable with the chuck table 38 and is different from the chuck table 38 in the size of the holding surface 38a. FIG. 3A is a sectional view schematically depicting the chuck table 38 fixed in the opening 4c of the base 4, and FIG. 3B is a sectional view schematically depicting the other chuck table 54. For example, the chuck table 38 is a chuck table for holding a disk-shaped workpiece 1 having a diameter of 300 mm, and the chuck table 54 is a chuck table for holding a disk-shaped workpiece 1 having a diameter of 8 inches. As illustrated in FIGS. 3A and 3B, the selected chuck table 38 or 54 is mounted to the table base 48a.

In the case where the operator or the supervisor of the treatment apparatus 2 makes a mistake in selection of the chuck table and an unsuitable chuck table is mounted to the treatment apparatus 2, the workpiece 1 is not suitably held. If the workpiece 1 is not suitably held, not only a predetermined treatment could not be applied to the workpiece 1, but also an unexpected shock or the like might be exerted on the workpiece 1 by a treatment, resulting in breakage of the workpiece 1. However, if staff for confirmation is added or the treatment apparatus 2 is equipped with a large scale confirmation mechanism, for preventing mis-mounting of the chuck table, treatment cost of the workpiece 1 by the treatment apparatus 2 would be raised.

In view of this, in the treatment apparatus 2 in the present embodiment, a determination unit for determining the kind of the chuck table is provided which is mounted to the table base 48a. The weight and shape of the chuck table differ on the basis of the kind of the chuck table. Therefore, when the motor driver 52 is controlled in order to rotate the chuck table at a predetermined speed, a torque outputted by the motor driver 52 differs depending on the kind of the chuck table. For example, the torques outputted by the motor driver 52 are preliminarily recorded on the basis of the kind of the chuck table. Then, by collating the torque outputted by the motor driver 52 when the chuck table as an object to the determined is rotated with each of the recorded torques, it is possible to determine the kind of the chuck table. The determination unit possessed by the treatment apparatus 2 will be described taking FIGS. 3A and 3B as examples. FIGS. 3A and 3B each depict an example of the configuration of the determination unit 50 connected to the motor driver 52 that controls the rotation of the servo motor 48c. The determination unit 50 includes, for example, a torque recording section 50a, a determination section 50b, and a reporting section that reports the result of determination performed by the determination section 50b.

Specifically, the determination unit 50 is a control device or controller that may be implemented using any type of device capable of processing data, such as a processor. Here, the processor may refer to a hardware built-in data processing device having a circuit physically structured to perform functions expressed in codes or instructions included in computer programs. Examples of the hardware built-in data processing device may include processing devices such as a microprocessor, a central processing unit (CPU), a processor core, a multiprocessor, an application-specific integrated circuit (ASIC), a field programmable gate array (FPGA), etc., but the scope of the present invention is not limited thereto.

The components, units or sections of the determination unit 50 may be dedicated portions of the processor for performing their respective functions, or they may be representations of different functions performed by the overall determination unit in response to control instructions provided from a program code. It is also contemplated that the components or units may be implemented as individual processors performing their respective functions.

In another embodiment, the components, units or sections of the determination unit 50 may also be implemented as software programs including codes or instruction, which are executed in one or more hardware devices such as a computer processor. Software programs may be hardcoded or programmed directly in a computer processor, or stored in a storage medium and retrieved and executed by the computer processor. Examples of the software program include not only machine language codes prepared by a compiler but also high-level codes executable by a computer by using an interpreter.

The torque recording section 50a includes a storage medium and records the torque outputted by the servo motor 48c when the table base 48a is rotated based on the kind of the chuck table mounted to the table base 48a. For example, various kinds of chuck tables are each mounted to the table base 48a, and, in each case, the table base 48a is accelerated at a predetermined acceleration until a predetermined rotational speed is reached, is thereafter rotated at the predetermined rotational speed, and is further decelerated at a predetermined acceleration until it is stopped. In this instance, the torque outputted by the servo motor 48c is detected by the motor driver 52, and is recorded by the torque recording section 50a in the storage medium.

A storage medium may be a non-transitory computer-readable recording medium such as magnetic media (e.g., hard disks, floppy disks, and magnetic tapes), optical media (e.g., CD-ROMs and DVDs), magneto-optical media (e.g., floptical disks), and hardware devices specifically configured to store and execute program commands (e.g., ROMs, RAMS, and flash memories).

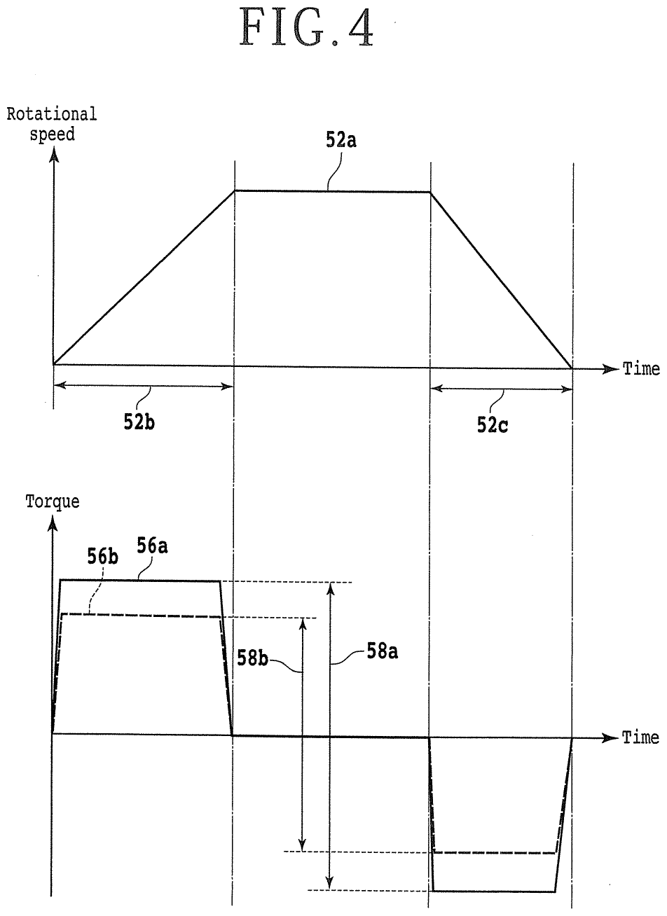

FIG. 4 depicts a graph 52a representing the relation of the rotational speed of the table base 48a and time, and graphs 56a and 56b representing the relation between the torques outputted by the servo motor 48c and time, as examples of the torque recorded by the torque recording section 50a. For example, the graph 56a is a graph representing the relation between the torque outputted by the servo motor 48c and time, in the case where the table base 48a with the chuck table 38 mounted thereto is accelerated, rotated, and decelerated as illustrated in the graph 52a. In addition, for instance, the graph 56b is a graph representing the relation between the torque outputted by the servo motor 48c and time, in the case where the table base 48a with the chuck table 54 mounted thereto is accelerated, rotated, and decelerated in the same manner as above.

The determination performed by the determination section 50b possessed by the determination unit 50 will be described. The determination section 50b is a processing device of the controller described above, that controls the motor driver 52 in such a manner as to rotate at a predetermined rotational speed the table base 48a to which the chuck table as an object to the determined is mounted. The torque outputted by the servo motor 48c in this instance is measured, and the torque thus measured is collated with each of the torques recorded in the torque recording section 50a. For example, the torque observed during an acceleration period 52b until the table base 48a reaches a predetermined rotational speed, or the torque observed during a deceleration period 52c until the table base 48a is stopped from the predetermined rotational speed, is collated with each of the torques recorded in the torque recording section 50a. Then, from among the torques recorded in the torque recording section 50a, the determination section 50b automatically extracts the torque coinciding with the observed torque. The kind of the chuck table as the object to be determined is determined to be the chuck table of the kind which has been mounted to the table base 48a when the extracted torque has been observed.

Note that from the viewpoint of the efficiency of the treatment in the treatment apparatus 2, an improvement of the servo motor 48c is under way such that friction generated by the rotation of the servo motor 48c is reduced. Therefore, the torque observed during when the servo motor 48c is rotating at a predetermined rotational speed is extremely small, and is not suitable as a torque to be referred to for collation. On the other hand, the torques observed during the acceleration period 52b and the deceleration period 52c of the table base 48a are comparatively large, with signal-to-noise (S/N) ratio being good, and, therefore, they are preferable as torques to be used at the time of collation.

Particularly, in the case where the torque observed during the acceleration period 52b by the determination section 50b through the motor driver 52 and the torque observed during the deceleration period 52c are both measured and the difference between these torques is evaluated, the S/N ratio is especially good and the accuracy of collation is extremely high. For example, as depicted in FIG. 4, a difference 58a between the torques in the graph 56a and a difference 58b between the torques in the graphs 56b are largely different from each other. Therefore, a mis-determination is hardly generated at the time of determining the kind of the chuck table.

Information on the kind of the chuck table determined by the determination section 50b is, for example, sent to the display monitor 44 mounted to the housing 4d of the treatment apparatus 2, to be displayed on the display monitor 44. For example, the operator of the treatment apparatus 2 or other person can confirm the kind of the chuck table mounted to the table base 48a, by checking the display monitor 44. In other words, the display monitor 44 can function as a reporting section constituting the determination unit 50. Alternatively, the information is sent to a control unit (not illustrated) that controls each of the components of the treatment apparatus 2. The contents of the treatment to be performed by the treatment apparatus 2 are preliminarily registered; for example, such information as the size of the workpiece 1 is registered. Then, the control unit may determine whether or not the kind of the chuck table mounted to the table base 48a is a chuck table which is suitable for holding the workpiece 1. For example, in the case where it is determined that an unsuitable chuck table is mounted to the treatment apparatus 2, the red lamp of the alarm lamp 46 disposed on the housing 4d may be turned on, to warn the operator of the treatment apparatus 2 or other person. In other words, the alarm lamp 46 can function as the reporting section constituting the determination unit 50.

As has been described above, the treatment apparatus 2 according to the present embodiment includes the determination unit 50 and is therefore able to automatically determine the kind of the chuck table mounted. Therefore, in the case where an erroneous kind of chuck table is mounted, an alarm can be issued to the operator of the treatment apparatus 2 or other person before a treatment of the workpiece 1 is performed by the treatment apparatus 2. For this reason, the treatment of the workpiece 1 is prevented from being performed in a state in which an erroneous kind of chuck table is mounted to the table base 48a. For determination of the kind of the chuck table, it is sufficient to connect the determination unit 50 to the motor driver 52 that controls the servo motor 48c, and other mechanical configurations are not needed. Therefore, the determination of the kind of the chuck table can be carried out at low cost.

Note that the present invention is not limited to the description of the above embodiment, and can be carried out with various modifications. For example, while a case in which the treatment unit is the cleaning unit 36 and the determination unit 50 determines the kind of the chuck table 38 has been mainly described in the above embodiment, an aspect of the present invention is not limited to this. For instance, the determination unit may be connected to a servo motor for rotating a chuck table 12 located under the cutting unit 30, and may determine the kind of the chuck table 12. In addition, while a case in which the treatment apparatus 2 is a cutting apparatus has been mainly described in the above embodiment, an aspect of the present invention is not limited to this. For example, the treatment apparatus 2 may be a grinding apparatus for grinding a workpiece, a laser processing apparatus for performing laser processing, or the like. An aspect of the present invention is applicable to an apparatus in which a chuck table is mounted and which includes a rotating mechanism for rotating the chuck table.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A treatment apparatus comprising:
a chuck table that has a holding surface mounting a workpiece thereon and holds the workpiece;
a table base to which the chuck table is detachably fixed;
a servo motor that rotates the table base around a rotational axis along a direction perpendicular to the holding surface of the chuck table mounted to the table base;
a treatment unit that treats the workpiece held by the chuck table; and
a determination unit that determines the kind of the chuck table mounted to the table base,
wherein the determination unit includes
a torque recording section in which a torque outputted by the servo motor when rotating the table base is recorded on a basis of the kind of the chuck table mounted to the table base,
a determination section that measures a torque outputted by the servo motor when rotating the table base with the chuck table mounted thereto, and collates the measured torque with each of the torques recorded in the torque recording section, to thereby determine the kind of the chuck table, and
a reporting section that reports a result of determination carried out by the determination section.

2. The treatment apparatus according to claim 1,
wherein the torque measured by the determination section is one of or both a torque during acceleration until the table base reaches a predetermined rotational speed and a torque during deceleration until the table base is stopped from the predetermined rotational speed.

3. The treatment apparatus according to claim 1,
wherein the treatment unit is a cleaning unit cleaning the workpiece.
